(19) United States
(12) Patent Application Publication
(10) Pub. No.: US 2008/0204116 A1
(43) Pub. Date: Aug. 28, 2008

(54) Sensing Apparatus And Method

(75) Inventor: David Alun James, Cambridgeshire (GB)

Correspondence Address: PATENT DOCKET ADMINISTRATOR;LOWENSTEIN SANDLER PC, 65 LIVINGSTON AVENUE, ROSELAND, NJ, 07068, US

(73) Assignee: SENSOPAD LIMITED, Harston, Cambridgeshire (GB)

(21) Appl. No.: 11/573,106

(22) PCT Filed: Aug. 9, 2005
(86) PCT No.: PCT/GB05/03120

§ 371 Date: Dec. 6, 2007

(30) Foreign Application Priority Data
Aug. 9, 2004 (GB) 0417686.3
Jul. 4, 2005 (GB) 0513710.4

(51) Int. Cl. H03K 17/945

(52) U.S. Cl. 327/517

(57) ABSTRACT

There is described a sensor for sensing the parameter, the sensor comprising a transmit aerial, an intermediate coupling element, a receive aerial electromagnetically coupled to the transmit aerial via the intermediate coupling element, a signal generator operable to generate a periodic excitation signal at a first frequency, and arranged to apply the generated excitation signal to the transmit aerial in order to generate a sense signal in the receive aerial indicative of the value of the parameter to be measured and a signal processor operable to process the signal induced in the receive aerial to determine a value representative of the parameter being measured. The intermediate coupling element includes a frequency shifter which, in response to the periodic excitation signal being applied to the transmit aerial, generates a sense signal in the receive aerial having a signal component at a second frequency which is different from the first frequency, and the signal processor is operable to process the signal at the second frequency to determine the value representative of the parameter being measured.

This application claims the right to priority based on British patent application number 0417686.3 filed on 9 Aug. 2004 and British patent application number 0513710.4 filed on 4 Jul. 2005, which are hereby incorporated by reference herein in their entirety as if fully set forth herein.

The invention described in this application relates to a sensing apparatus and method and has particular, but not exclusive, relevance to a position sensor for sensing the relative position of two members.

UK patent application GB 2374424A describes an inductive position sensor in which a transmit aerial and a receive aerial are formed on a first member, and a resonant circuit having an associated resonant frequency is formed on a second member which is movable relative to the first member. An excitation signal having a frequency component at or near the resonant frequency of the resonant circuit is applied to the transmit aerial resulting in the generation of a magnetic field having a magnetic field component at or near the resonant frequency of the resonant circuit. The generated magnetic field induces a resonant signal in the resonant circuit, which in turn induces a sense signal in the receive aerial that varies with the relative position of the first and second members. The sense signal is processed to determine a value representative of the relative position of the first and second members.

In the position sensor described in GB 2374424A, the resonant signal induced in the resonant circuit is generated as a result of an electromotive force which is proportional to the rate of change of the magnetic field component at or near the resonant frequency. As the impedance of the resonant circuit is substantially entirely real at the resonant frequency, the resonant signal is approximately in phase with the electromotive force and accordingly is approximately 90° out of phase with the frequency component of the excitation signal near the resonant frequency. The sense signal induced in the receive aerial is generally in phase with the resonant signal, and therefore the sense signal is also approximately 90° out of phase with the component of the excitation signal near the resonant frequency of the resonant circuit.

The sense signal is synchronously detected using a signal which has the same frequency as, but is in phase quadrature with, the frequency component of the excitation signal near the resonant frequency of the resonant circuit. By using such phase sensitive detection noise which is at the same frequency as, but is in phase quadrature with, the frequency component of the sense signal near the resonant frequency of the resonant circuit is reduced. However, a problem with such an inductive sensor is that noise can occur having the same frequency as, and in phase with, the sense signal. This noise component is not removed by the phase sensitive detection and therefore affects the accuracy of the position measurement. Such a noise component can be generated through signal coupling between components of the inductive position sensor, either directly or indirectly via a magnetically permeable or conductive body which is in close proximity with the inductive position sensor.

This problem also arises in inductive position sensors in which a transmit aerial on a first member is directly coupled to a receive aerial, which may or may not include a resonant circuit, on a second member.

According to a first aspect of the invention, there is provided a sensor in which a transmit aerial is electromagnetically coupled to a receive aerial via an intermediate coupling element. A signal generator generates a periodic excitation signal at a first frequency, and applies the generated excitation signal to the transmit aerial in order to generate a sense signal in the receive aerial which is processed to determine a value representative of the parameter being measured. The intermediate coupling element includes a frequency shifter which causes, in response to the periodic excitation signal being applied to the transmit aerial, signal components to be generated at a second frequency which is different from the first frequency, and the signal processor processes signal at the second frequency to determine the value representative of the parameter being measured. In this way, the effect of noise at the first frequency is reduced.

According to a second aspect of the invention, there is provided a proximity indicating apparatus comprising a first member comprising a transmit aerial, a second member comprising a coupling element operable to couple electromagnetically with the transmit aerial, and a signal generator operable to generate an excitation signal, and arranged to apply the generated excitation signal to the transmit aerial in order to generate a signal in the coupling element. The coupling element comprises a light emitting diode which, in response to the periodic excitation signal being applied to the transmit aerial, is operable to emit light if the signal induced in the coupling element is sufficient to make the light emitting diode conducting.

Various embodiments of the invention will now be described with reference to the attached figures in which:

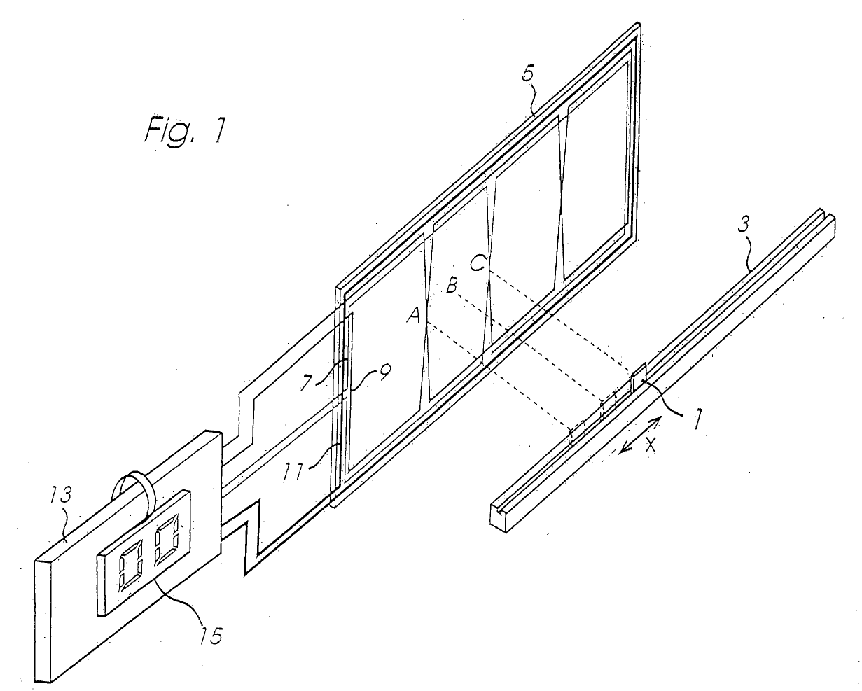

FIG. 1 schematically shows a perspective view of a position sensor according to a first embodiment of the invention;

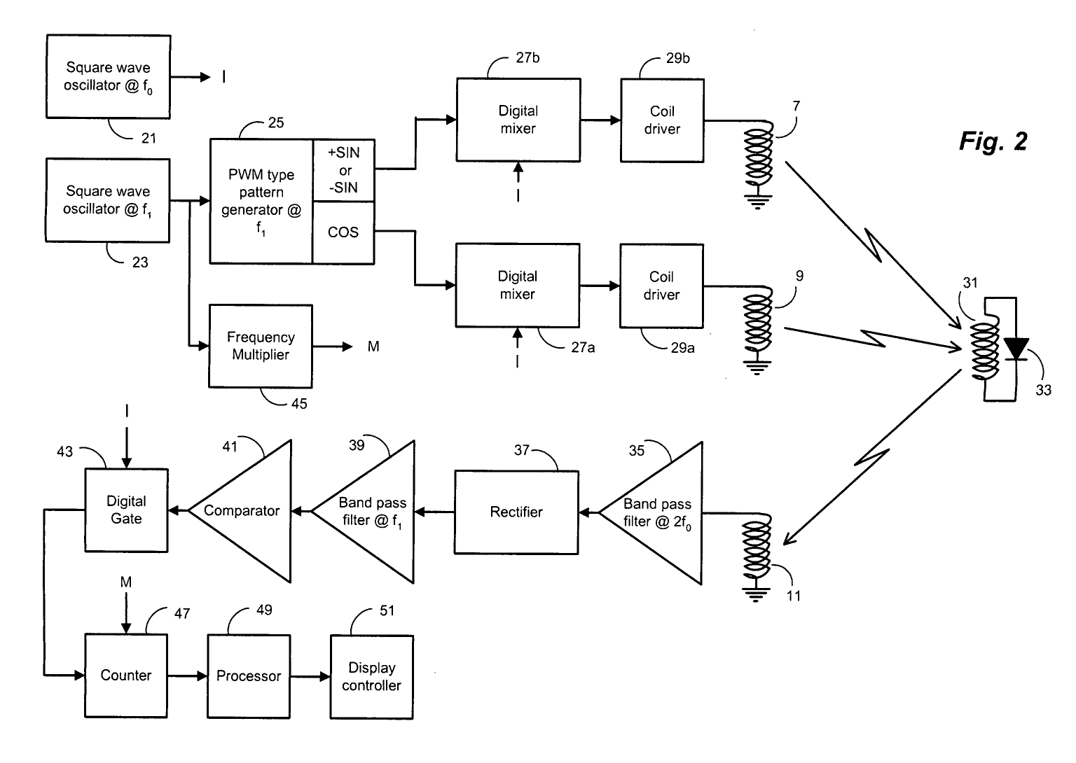

FIG. 2 schematically shows the main signal generating and processing circuitry of the position sensor illustrated in FIG. 1;

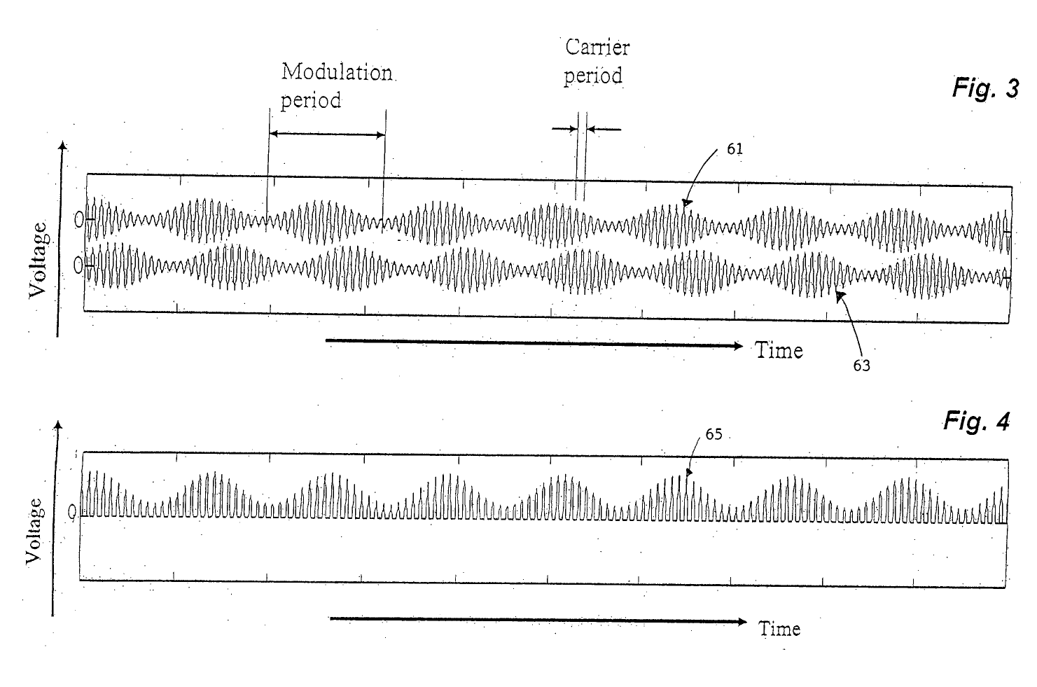

FIG. 3 is a timing diagram showing signals applied to a sine winding and a cosine winding illustrated in FIG. 2;

FIG. 4 is a timing diagram showing a signal generated in an intermediate coupling element illustrated in FIG. 2;

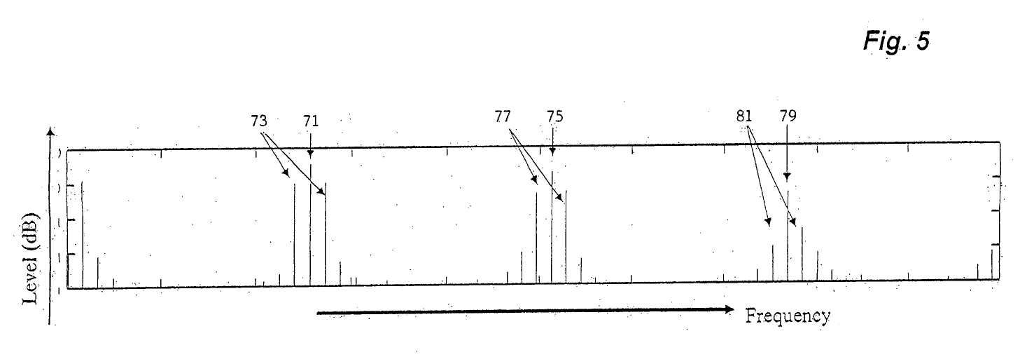

FIG. 5 is a graph showing the frequency components of the signal illustrated in FIG. 4;

FIG. 6 is a timing diagram showing a signal component at a first frequency induced in a sense winding illustrated in FIG. 2;

FIG. 7 is a timing diagram showing a signal component at a second frequency which is induced in the sense winding illustrated in FIG. 2;

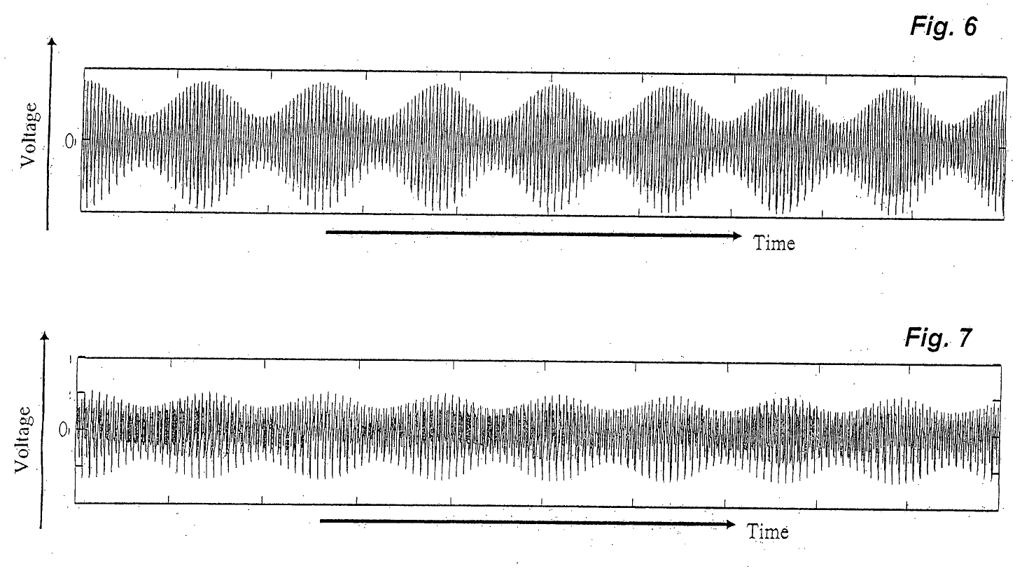

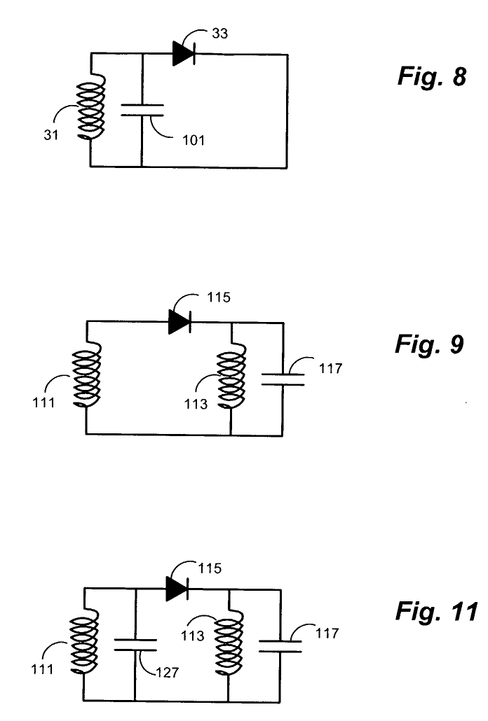

FIG. 8 is a circuit diagram for a first alternative intermediate coupling element to the intermediate coupling element illustrated in FIG. 2;

FIG. 9 is a circuit diagram for a second alternative intermediate coupling element to the intermediate coupling element illustrated in FIG. 2;

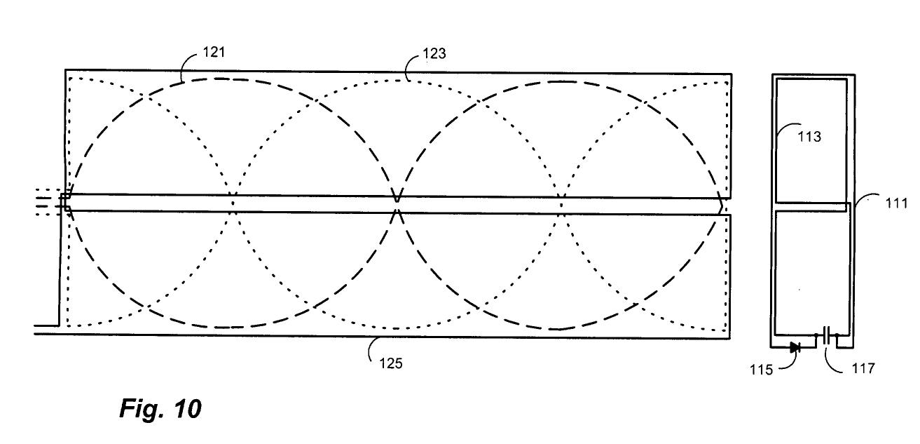

FIG. 10 is a plan view of the layout of the second alternative intermediate coupling element illustrated in FIG. 9 together with the layout of a sine winding, cosine winding and sense winding arrangement to be used in conjunction with the second alternative intermediate coupling element;

FIG. 11 is a circuit diagram for a third alternative intermediate coupling element to the intermediate coupling element illustrated in FIG. 2;

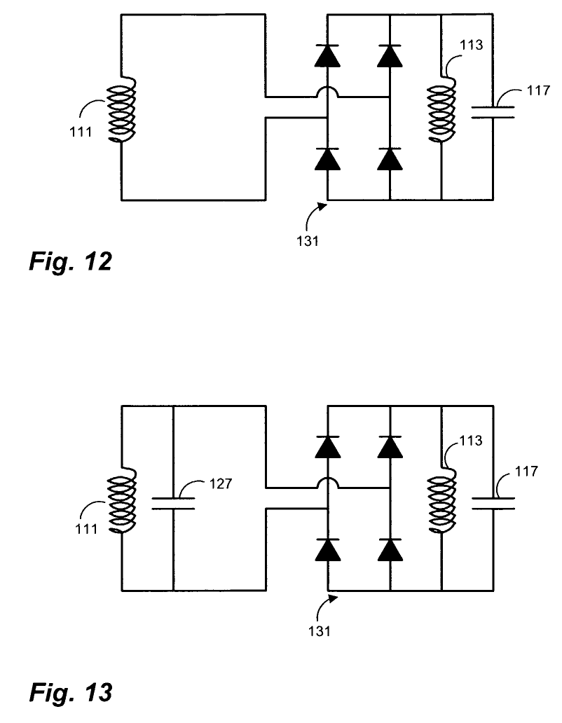

FIG. 12 is a circuit diagram for a fourth alternative intermediate coupling element to the intermediate coupling element illustrated in FIG. 2;

FIG. 13 is a circuit diagram for a fifth alternative intermediate coupling element for the intermediate coupling element illustrated in FIG. 2;

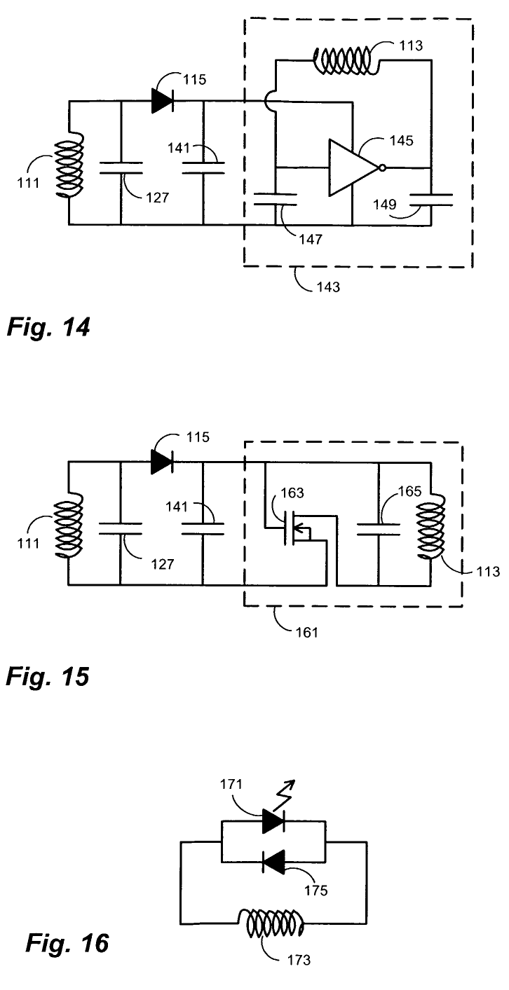

FIG. 14 is a circuit diagram for a sixth alternative intermediate coupling element to the intermediate coupling element illustrated in FIG. 2;

FIG. 15 is a circuit diagram for a seventh alternative intermediate coupling element to the intermediate coupling element illustrated in FIG. 2; and

FIG. 16 is a circuit diagram for an alternative intermediate coupling element including a light emitting diode.

### First Embodiment

FIG. 1 schematically shows a position sensor for detecting the position of a sensor element 1 which is slidably mounted to a support 3 to allow linear movement along a measurement direction (the direction X in FIG. 1). A printed circuit board (PCB) 5 extends along the measurement direction adjacent to the support 3 and has printed thereon conductive tracks which form a sine winding 7, a cosine winding 9 and a sense winding 11, each of which are connected to a control unit 13. A display 15 is also connected to the control unit 13 for displaying a number representative of the position of the sensor element 1 along the support 3.

The layout of the sine winding 7 is such that current flowing through the sine winding 7 generates a first magnetic field having a magnetic field component B₁ perpendicular to the PCB 5 which varies along the measurement direction according to one period of the sine function over a distance L. Similarly, the layout of the cosine winding 9 is such that current flowing through the cosine winding 9 generates a second magnetic field having a magnetic field component B₂ perpendicular to the PCB 5 which varies along the measurement direction according to one period of the cosine function over the distance L. In this embodiment, the layout of the sine winding 7, the cosine winding 9 and the sensor winding 11 on the PCB 5 is identical to the layout of the corresponding windings of the position sensor described in GB 2374424A, whose content is hereby incorporated by reference.

The control unit 13 includes excitation signal generating circuitry (not shown in FIG. 1) for applying excitation signals to the sine winding 7 and the cosine winding 9, and sense signal processing circuitry (not shown in FIG. 1) for processing a sense signal in the sense winding 11. In this way, the sine winding 7 and the cosine winding 9 form a transmit aerial and the sense winding 11 forms a receive aerial. In this embodiment, the layout of the sine winding 7, the cosine winding 9 and the sense winding 11 results in the electromotive forces directly induced in the sense winding 11 by current flowing through the sine winding 7 and/or the cosine winding 9 generally balancing each other out. In other words, in the absence of the sensor element 1, the sense signal directly generated in the sense winding 11 by current flowing through the sine winding 7 and/or the cosine winding 9 is small. Using the sine winding 7 and the cosine winding 9 for the transmit aerial has the further advantage that the electromagnetic emissions resulting from current flowing through the sine winding 7 and/or the cosine winding 9 diminish with distance at a faster rate than for a single conductive loop. This allows larger drive signals to be used while still satisfying regulatory requirements for electromagnetic emissions.

The excitation signal generating circuitry and the sense signal processing circuitry will now be described in more detail with reference to FIG. 2. As shown, the control unit 13 includes a first square wave oscillator 21 which generates a square wave signal I at a frequency f₀, which will hereafter be called the carrier frequency, which in this embodiment is 2 MHz. The control unit 13 also includes a second square wave oscillator 23 which outputs a square wave signal at a frequency f₁, hereafter called the modulation frequency, which in this embodiment is 3.9 kHz.

The signal output by the second square wave oscillator 23 is input to a pulse width modulation (PWM) type pattern generator 25 which generates digital data streams representative of sinusoidal signals at the modulation frequency f₁. In particular, the PWM type pattern generator 25 generates two modulation signals which are in phase quadrature with one another, namely a cosine signal COS and either a positive sine or a negative sine signal ±SIN.

The cosine signal COS is output by the PWM type pattern generator 25 to a first digital mixer 27a, in this embodiment a NOR gate, which mixes the cosine signal with the digital signal I at the carrier frequency f₀ to generate a signal Q(t). The sine signal ±SIN is output by the PWM type pattern generator 25 to a second digital mixer 27b, in this embodiment a NOR gate, together with the digital signal I at the carrier frequency f₀ to generate a digital representation of either an in-phase signal I(t) (if the +SIN signal is output) or an anti-phase signal I(t) (if the −SIN signal is output). In this embodiment, the modulation depth applied to the digital signal I at the carrier frequency f₀ when mixed with a signal at the modulation frequency f₁ by the digital mixers is 50% (i.e. the amplitude of the signal at the carrier frequency f₀ varies between a maximum value and half the maximum value).

The digital signals output from the first and second digital mixers 27 are input to respective ones of first and second coil driver circuits 29a, 29b and the resulting amplified signals output by the coil drivers 29a, 29b are then applied to the cosine winding 9 and the sine winding 7 respectively. The digital generation of the drive signals applied to the sine winding 7 and the cosine winding 9 introduces high frequency harmonic noise. However, the coil drivers 29a, 29b remove some of this high frequency harmonic noise, as does the frequency response characteristics of the cosine winding 9 and the sine winding 7. FIG. 3 schematically shows the signal 61 in the cosine winding 9 and the signal 63 in the sine winding 7. The frequency spectrum of the signal 61 in the cosine winding 9 and the signal 63 in the sine winding 7 includes frequency components at f₀±f₁ and also, due to the modulation depth applied to the digital signal I at the carrier frequency f₀ being less than 100%, at f₀.

As shown in FIG. 2, an intermediate coupling element, which is provided on the sensor element 1, is formed by a winding 31 which is connected across the terminals of a diode 33. In particular, the intermediate coupling element has a printed circuit board on which the winding 31 and the diode 33 are formed. The magnetic field component perpendicular to the PCB 5 generated by the sine winding 7 and the cosine winding 9 generates an electromotive force in the intermediate coupling element. As shown in FIG. 4, due to the non-linear voltage to current relationship of the diode 33, this electromotive force results in a voltage waveform 65 being generated across the ends of the winding 31 which corresponds in shape to the positive part of the excitation waveforms, minus one diode drop voltage, with the phase of the signal component at the modulation frequency f₁ varying in dependence on the position of the sensor element 1. The blocking of the negative part of the waveform by the diode 33 has the effect of introducing harmonic components into the current signal induced in the intermediate coupling element.

FIG. 5 shows the frequency spectrum of the signal induced in the intermediate coupling element. As shown, in addition to a signal component 71 at the carrier frequency f₀ and modulation side bands 73 at frequencies f₀±f₁, a signal component 75 at frequency 2f₀ with modulation side bands 77 at frequencies 2f₀±f₁ and a signal component 79 at frequency 3f₀ modulation side bands 81 at frequencies 3f₀+f₁ are also present (along with other signal components at higher harmonics of the carrier frequency f₀ and associated modulation side bands, which are not shown in FIG. 5). Further, as can be seen in FIG. 5, in addition to the primary side bands additional side bands are formed around each of the harmonics of the carrier frequency f₀ (i.e. at 2f₀±2f₁, 3f₀±2f₁, etc).

In this specification, the signal component at twice the carrier frequency f₀ is referred to as the second harmonic, the signal component at three times the carrier frequency f₀ is referred to as the third harmonic and so on.

Returning to FIG. 2, the current signal induced in the intermediate coupling element generates a magnetic field which induces a signal in the sense winding 11. The frequency spectrum of the signal induced in the sense winding 11 will include signal components at the same frequencies as the frequency components induced in the intermediate coupling element. FIGS. 6 and 7 respectively show the signal components induced in the sense winding 11 around the second harmonic of the carrier frequency f₀ and the third harmonic of the carrier frequency f₀. As shown, each of these harmonics of the carrier frequency f₀ is modulated at the modulation frequency f₁ with substantially the same phase, which is dependent on the position of the sensor element 1 relative to the PCB 5.

In this embodiment, the signal induced in the sensor winding 11 is filtered by a band pass filter 35, which passes signal components around the second harmonic of the carrier frequency f₀ (i.e. in this embodiment around 4 MHz), so that the signal output by the band pass filter 35 corresponds to the signal shown in FIG. 6.

The signal output by the band pass filter 37 is then input to a rectifier 37, which in this embodiment is simply a diode, which rectifies the signal and the resulting rectified signal output by the rectifier 37 is input to a second band pass filter 39 which passes frequencies at or close to the modulation frequency f₁. Accordingly, the second band pass filter 39 outputs a signal at the modulation frequency f₁ whose phase is dependent on the position of the sensor element 1 relative to the PCB 5. Then, in the same way as the position sensor discussed in GB 2374424 A, the signal at the modulation frequency f₁ is input to a comparator 41 to form a square wave signal, and this square wave signal is used to control a digital gate 43 which passes a square wave signal at the carrier frequency f₀ when the output of the comparator 41 is high, but blocks the square wave signal at the frequency f₀ when the output of the comparator 41 is low.

The square wave signal at the modulation frequency f₁ output by the second square wave oscillator 23 is also input to a frequency multiplier 45 which multiplies the frequency by a factor of sixteen, and therefore outputs a signal M at a frequency of 62.4 kHz. The pulses of the square wave signal passed by the digital gate 43 are input to a counter 47, and the multiplied signal M is also input to the counter 45 to provide a reference timing. In the same manner as discussed in GB 2374424A, the counter 47 counts the number of pulses received in a time frame whose duration corresponds to one period of the multiplied signal M (i.e. one sixteenth of the period of the modulation frequency), outputs the resultant count value and then resets to zero before counting the number of pulses in the next time frame. The resulting count values are input to a processor 49 which converts the count values into a position value. This position value is then output to the display controller 51 which generates a control signal causing the display 15 to show the position value.

As discussed above, the PWM type pattern generator 25 outputs either a +SIN signal or a −SIN signal. As discussed in GB 2374424A, by averaging the position readings obtained using the +SIN signal and the −SIN signal, the effect of any fixed phase offsets introduced by the intermediate coupling element or the signal processing circuitry on the accuracy of the position measurement is significantly reduced.

This embodiment has a number of advantages over the position sensor described in GB 2374424A. In particular:
1. As the signal processing circuitry determines the position value using signal components at the second harmonic of the carrier frequency, noise originating from the excitation signal generating circuitry is significantly reduced.
2. As there is no need to perform synchronous detection, a diode and a filter may be used to demodulate the sense signal thereby reducing the complexity and the cost of the signal processing circuitry.

In this embodiment, the phase of the modulation of the second harmonic of the carrier frequency f₀ (i.e. 2f₀) at the modulation frequency f₁ is measured, which has the advantage that each phase reading corresponds unambiguously to a position reading (bearing in mind that in this embodiment the position readings vary over one period of the sine winding 7 and cosine winding 9). It will be appreciated that this signal component only exists due to the less than full modulation of the digital signal I at the carrier frequency f₀ at the modulation frequency f₁ which allows non-linear mixing of a signal component at the carrier frequency f₀ with the modulation sidebands at frequencies f₀±f₁.

### Second Embodiment

In the first embodiment, the intermediate coupling element is formed by a winding connected in parallel with a diode. A second embodiment will now be described with reference to FIG. 8 in which the intermediate coupling element of the first embodiment is replaced by an intermediate coupling element having a low impedance property. The remaining components of the second embodiment are identical to the corresponding components of the first embodiment.

As shown in FIG. 8, in this embodiment the intermediate coupling element is formed by a winding 31, a diode 33 and a capacitor 101 which are all connected in parallel. The parallel connection of the winding 31, which has an associated inductance, and the capacitor 101 forms a circuit in which the reactance of the winding 31 is effectively cancelled out by the reactance of the capacitor 101 at a particular frequency (hereafter called the low impedance frequency). In this embodiment, the inductance of the winding 31 and the capacitance of the capacitor 101 are set so that this low impedance frequency is substantially the same as the carrier frequency f₀, i.e. 2 MHz. In particular, in this embodiment the capacitor 101 has a capacitance of 6.3 nF and the winding 31 has an inductance of 1 μH.

By substantially matching the low impedance frequency of the intermediate coupling element to the carrier frequency of the excitation signal, the magnitude of the current signal component induced in the intermediate coupling element is significantly increased in comparison with the first embodiment, and accordingly the signal component induced in the sense winding 11 is correspondingly increased.

### Third Embodiment

In the first embodiment, the winding 31 in the intermediate coupling element couples with both the transmit aerial and the receive aerial. As the signal processing circuitry uses the signals around the second harmonic of the carrier frequency f₀ to determine a value indicative of the position of the sensor element 1 relative to the PCB 5, it is desirable to reduce the coupling of signal at the carrier frequency f₀ into the sense winding 11.

A third embodiment will now be described with reference to FIGS. 9 and 10 in which the layout of the sine winding 7, the cosine winding 9 and the sense winding 11 in the first embodiment is changed, and the intermediate coupling element of the first embodiment is replaced by an alternative intermediate coupling element.

As shown in FIG. 9, in this embodiment the intermediate coupling element has an input winding 111 and an output winding 113. A diode 115 is connected between one end of the input winding 111 and one end of the output winding 113, with the other end of the input winding 111 being directly connected to the other end of the output winding 113. A capacitor 117 is provided in parallel with the output winding 113. In this embodiment, the output winding 113 has an inductance of 1 μH and the capacitor 117 has a capacitance of 1.6 nF so that at the second harmonic of the carrier frequency f₀ (i.e. 4 MHz), the reactance of the capacitor 117 effectively cancels out the reactance of the output winding 113 so that a low impedance occurs.

FIG. 10 shows in more details the layout of the sine winding (indicated by the dashed line 121), the cosine winding (indicated by the dotted line 123), the sense winding (indicated by the continuous line 125) and the intermediate coupling element in this embodiment. As shown, the layout of the sine winding 121 and the cosine winding 123 is the same as the layout of the sine winding 7 and the cosine winding 9 of the first embodiment except that the conductive tracks are displaced relative to the central axis in accordance with sinusoidal functions which are 90° out of phase with each other, rather than square wave functions which are 90° out of phase with each other. This has no substantial effect on the operation of the position sensor.

The sense winding 125 is formed by a direct conductive track in a figure of eight winding (with no direct electrical connection occurring at the crossing point) so that two current loops are effectively formed, with current flowing around one current loop in the opposite direction to the direction the current flows around the other current loop.

The input winding 111 of the intermediate coupling element is formed a single current loop arranged so that any current flowing around the input winding 111 induces equal and opposite electromotive forces in the two current loops of the sense winding 125 respectively. In other words, the input winding 111 is balanced with respect to the sense winding 125 so that negligible signal is induced in the sense winding 125 as a result of current flowing through the input winding 111.

The output winding 113 of the intermediate coupling element is formed by a conductive track in a figure of eight pattern (with no direct electrical connection at the crossing point) aligned in the same direction as the figure of eight pattern of the sense winding, so that the output winding effectively forms two current loops with current flowing one way around one current loop and the other way around the other current loop. With such an arrangement, current flowing in the current loops of the output winding 113 induces signals in respective current loops of the sense winding 125 which are complementary. Further, the output winding 113 is balanced with respect to the sine winding 121 and the cosine winding 123. Also, the output winding 113 is balanced with respect to the input winding 111.

Therefore, in use, an alternating current flowing in the sine winding 121 and the cosine winding 123 induces a signal in the input winding 111 but induces negligible signal in the output winding 113, and the current flowing in the input winding 111 induces negligible signal in the sense winding 125. Further, current flowing in the output winding 113 induces a signal in the sense winding 125 but induces negligible signal in the sine winding 121 and the cosine winding 123. In this way, signal noise in the sense winding 125 is reduced.

### Fourth Embodiment

In the third embodiment, the output winding 113 has a capacitor 117 connected in parallel so that at around twice the carrier frequency f₀, the reactance of the output winding 113 is substantially cancelled by the reactance of the capacitor 117 thereby increasing the strength of the signal component at twice the carrier frequency f₀. A fourth embodiment will now be described with reference to FIG. 11 in which a capacitor 127 is added to the intermediate coupling element of the third embodiment, the capacitor 127 being connected in parallel with the input winding 111. The remaining components of the position sensor of the fourth embodiment are identical to the corresponding components of the position sensor of the third embodiment.

The capacitor 127 has a capacitance which is selected so that at around the carrier frequency f₀ the reactance of the capacitor 127 substantially cancels out the reactance of the input winding 111. In this way, the current signal induced in the intermediate coupling element is increased, resulting in an increase in the signal component at twice the carrier frequency f₀ flowing through the output winding 113.

### Fifth Embodiment

In the preceding embodiments, the intermediate coupling element includes a non-linear component in the form of a diode which performs half-wave rectification. A fifth embodiment will now be described with reference to FIG. 12 in which the intermediate coupling element of the third embodiment is modified by replacing the diode 115 with a diode bridge arrangement 131. The remaining components of the position sensor of the fifth embodiment, including the lay-out of the input winding 111 and the output winding 113 of the intermediate coupling element, are the same as for the position sensor of the third embodiment.

It will be appreciated that the diode bridge arrangement 131 acts as a full-wave rectifier. Although the diode bridge arrangement 131 introduces two diode voltage drops, if the electromotive force induced in the intermediate coupling element by virtue of the excitation of the transmit aerial is sufficiently high then the full-wave rectification will increase the signal level flowing through the output winding 113 at around twice the carrier frequency f₀, and accordingly will increase the strength of the signal component induced in the sense winding 125 at around twice the carrier frequency f₀. In other words, if the electromotive force induced in the input winding is sufficiently large then it is advantageous to include a full-wave rectifier in the intermediate coupling element, otherwise it is preferred to use a half-wave rectifier.

### Sixth Embodiment

In the sixth embodiment, the intermediate coupling element of the fifth embodiment is modified by adding a capacitor 127 in parallel with the input winding 111, with the capacitance of the capacitor 127 being selected so that at the carrier frequency f₀ the reactance of the input winding 111 is substantially cancelled out by the reactance of the capacitor 127. The remaining components of the position sensor of the fifth embodiment are unchanged.

As discussed in the fourth embodiment, by introducing the capacitor 127 the current signal level induced in the input winding 111 is increased, resulting in a corresponding increase in the signal induced in the sense winding.

### Seventh Embodiment

In the previous embodiments, harmonics of the excitation frequency fₒ are generated by incorporating a non-linear element into the intermediate coupling element. Accordingly, the signal induced into the sense winding 11 has signal components at harmonics of the carrier frequency f₀ which may be processed to determine position of the sensor element 1 relative to the PCB 5.

A seventh embodiment will now be described with reference to FIG. 14 in which the frequency of the signal induced in the sense winding 11 is arbitrarily set, and accordingly need not be a harmonic of the carrier frequency f₀. By moving away from harmonics of the carrier frequency f₀, the noise caused by direct or indirect cross-talk from the excitation signal generating circuitry is further reduced. This is particularly relevant when, as in the previous embodiments, digital signal generation is used in the excitation signal generating circuitry because such digital generation introduces signal components at harmonics of the carrier frequency f₀.

In the seventh embodiment, the intermediate coupling element of the fourth embodiment is replaced by the intermediate coupling element whose circuit design is illustrated in FIG. 14, and the pass frequency of the first band pass filter 35, which filters the signal induced in the sense winding 11, is changed to match the oscillation frequency of an oscillator forming part of the circuit illustrated in FIG. 14. The remaining components of the position sensor of the fourth embodiment are unchanged.

As shown in FIG. 14, in the same manner as the intermediate coupling element of the third embodiment, the intermediate coupling element of the seventh embodiment includes an input winding 111, which in this embodiment has an inductance of 1 μH, connected in parallel with a capacitor 127 having a capacitance of 6.3 nF so that at the carrier frequency f₀ the reactance of the input winding 111 is substantially cancelled out by the reactance of the capacitor 127. In this embodiment, the layout of the input winding 111 is the same as the layout of the input windings of the third to sixth embodiments.

One terminal of a diode 115 is connected to one end of the input winding ill, while a smoothing capacitor 141 is connected between the other terminal of the diode 115 and the other end of the input winding 111. In this way, the diode 115 acts as a half-wave rectifier while the smoothing capacitor 141 acts as a low pass filter. In this embodiment, the smoothing capacitor 141 has a capacitance of 100 nF so that the signal at the carrier frequency f₀ is substantially blocked but the signal at the modulation frequency f₁ is substantially passed.

The signal passed by the smoothing capacitor 141 acts as a power signal for an oscillator circuit 143. In this embodiment, the oscillator circuit 143 is formed by a CMOS inverter 145 and an output winding 113 is connected across the input and output terminals of the CMOS inverter 145. In this embodiment, the output winding 113 has an inductance of 1 μH and has a layout which is the same as the layout of the output windings of the third to sixth embodiments. A capacitor 147 having a capacitance of 1.8 nF connects the input terminal of the CMOS inverter 145 to one of the power supply rails, and a capacitor having a capacitance of 1.8 nF connects the output terminal of the CMOS inverter 145 to the same power supply rail.

The oscillation frequency of the oscillator circuit 143 is determined by the inductance of the output winding 113 and the capacitances of the capacitors 147, 149 connected between the input terminal and the output terminal of the CMOS inverter and one of the power supply rails. In this embodiment, the oscillation frequency is set at about 5 MHz, and accordingly is not a harmonic of the carrier frequency f₀, which is 2 MHz. The signal induced in the oscillator circuit 143 in response to an electromotive force being induced in the input winding 111 is accordingly substantially a sinusoidal signal at the oscillation frequency (i.e. 5 MHz) modulated by a signal at the modulation frequency f₁ (i.e. 3.9 kHz), with the phase of the modulation matching the phase of the component of the signal induced in the input winding 111 at the modulation frequency.

The signal induced in the sense winding will therefore have a signal component at the oscillation frequency of 5 MHz modulated at the modulation frequency f₁ of 3.9 kHz. As set out above, in this embodiment the pass band of the band pass filter 35 is set to the oscillation frequency (i.e. 5 MHz), so that the signal component at around 5 MHz is input to the rectifier 37. The processing of the sense signal then follows in the same way as discussed in the first embodiment.

### Eighth Embodiment

In the seventh embodiment, the output winding 113 forms part of an oscillator having an oscillation frequency which is not a harmonic of the carrier frequency f₀. In this way, noise caused by harmonics of the carrier frequency f₀ can be filtered out of the signal induced in the sense winding 11.

In the eighth embodiment, the oscillator circuit 41 of the seventh embodiment is replaced by an alternative oscillator circuit 161 in which the signal across the smoothing capacitor 141 is applied across the gate and source terminals of a MOSFET 163. Further, the gate terminal of the MOSFET 163 is connected via the output winding 113 (which in this embodiment has the same layout as the layout of the output windings in the third to seventh embodiments), which is connected in parallel with a capacitor 165, to the drain terminal of the MOSFET 163. In this way, an oscillator is formed having an oscillation frequency which is determined by the inductance of the output winding 113 and the capacitance of the capacitor 165. In this embodiment, the oscillation frequency of the oscillating circuit 161 is set to 4 MHz so that it is at the second harmonic of the carrier frequency f₀.

In the same manner as discussed in the seventh embodiment, the signal input to the oscillator circuit 161 is modulated at the oscillation frequency. When the signal is not sufficiently high to make the MOSFET conducting, the oscillator circuit 161 is allowed to oscillate. However, when the signal is sufficiently high to make the MOSFET conducting, the oscillator circuit 161 is shorted and rings down. In this way, the modulation at the modulation frequency f₁ is transferred to the oscillation frequency but is inverted (i.e. 180° phase shifted).

The processing of the signal induced in the sense winding 111 proceeds in the same manner as described for the position sensor in the seventh embodiment, except that the 180° phase shift introduced in the intermediate coupling element is also taken into account.

### MODIFICATIONS AND FURTHER EMBODIMENTS

As explained in the first embodiment, it is preferred to utilise a less than full modulation of the digital signal I at the carrier frequency f₀ by the modulation frequency f₁ so that signal components at 2f₀±f₁ are generated by the non-linear element in the intermediate coupling element. Alternatively, full modulation could be used in which case, for example, the signal components at 2f₀±2f₁ could be processed. However the doubling of the modulation frequency will cause a doubling of the phase leading to each phase reading corresponding to the different possible position readings. This ambiguity in the position reading can be accounted for by either restricting the range of movement of the sensor element 1 to half the period of the sine winding 7 and cosine winding 9 or by taking an additional coarse position measurement.

In the seventh and eighth embodiments, the power for the oscillator circuits is provided by the signal coupled into the intermediate coupling element from the transmit aerial. Alternatively, the intermediate coupling element could include a power source for providing power to the oscillator circuit.

In the first to sixth and eighth embodiment, the processing circuitry processes the signal induced in the sense winding at twice the frequency of the carrier frequency f₀ (i.e. the second harmonic). It is preferred to process an even harmonic of the carrier frequency f₀ (i.e. 2f₀, 4f₀, 6f₀ etc) because the digital excitation signal generation circuitry generally generates noise at odd harmonics of the carrier frequency f₀ (i.e. 3f₀, 5f₀ etc) and accordingly by processing at an even harmonic of the carrier frequency f₀ noise is reduced.

In the eighth embodiment, the oscillation frequency is set to the second harmonic of the carrier frequency f₀, i.e. 4 MHz. It is preferred that the oscillation frequency is set equal to one of the harmonics of the carrier frequency because this results in higher signal strength, although in principle the oscillation frequency could be set to a frequency away from a harmonic of the carrier frequency f₀.

Although in the third to sixth embodiments a capacitor 117 is preferably connected in parallel with the output winding 113 and has a capacitance set so that at the detection frequency of the signal processing circuitry (which in those embodiments is 4 MHz) the reactance of the capacitor 117 effectively cancels out the reactance of the output winding 113 to give increased signal level, the capacitor 117 is not essential.

As described in the first embodiment, a fixed phase shift is removed by effectively taking two measurements of the position with the phase of the signal applied to the sine coil 7 being reversed between measurements. It will be appreciated that in alternative embodiments, the reverse measurement need only be performed intermittently which has the advantage of increasing the measurement update rate. Alternatively, a predetermined value for the phase shift, determined by a factory calibration, could be subtracted from a single phase measurement. However, this is not preferred because it cannot allow for environmental factors which vary the fixed phase shift.

It will be appreciated that if the phase angle measured using the −SIN signal is subtracted from, rather than added to, the phase angle measured using the +SIN signal then the position-dependent phase shift would be removed to leave a value equal to twice the fixed phase shift. In an embodiment, an intermediate coupling element is manufactured using one or more components having a high sensitivity to environmental factors so that the variation of the fixed phase shift is predominantly due to environmental factors. In this way, a measurement of the fixed phase shift can be indicative of an environmental factor, for example temperature in a constant humidity environment or humidity in a constant temperature environment. Typically, this would involve storing in the control circuitry of the inductive sensor a factory calibration between the measured fixed phase shift and the corresponding value of the environmental factor. Other modifications which enable detection of a parameter other than position are described in PCT application No. ______ entitled “Inductive Sensor” filed on even date herewith and claiming priority from British patent application number 0417686.3.

In the described embodiments, the sine coil 7 and the cosine coil 9 are arranged so that their relative contributions to the total magnetic field component perpendicular to the PCB 5 vary in accordance with position along the measurement direction. In particular, the sine and cosine coils have an alternate twisted loop structure. However, it would be apparent to a person skilled in the art that an enormous variety of different excitation winding geometries could be employed to form transmit aerials which achieve the objective of causing the relative proportions of the first and second transmit signals appearing in the ultimately detected combined signal to depend upon the position of the sensor element in the measurement direction.

The position sensor described in the first embodiment could be adapted to measure a linear position along a curved line, for example a circle (i.e. a rotary position sensor) by varying the layout of the sine coil and the cosine coil in a manner which would be apparent to persons skilled in the art. The position sensor could also be used to detect speed by periodically detecting the position of the sensor element as the sensor element moves along the measurement path, and then calculating the rate of change of position.

While in the described embodiments, the excitation windings are formed by conductive tracks on a printed circuit board, they could also be provided on a different planar substrate or, if sufficiently rigid, could even be free standing. Further, it is not essential that the excitation windings are planar because, for example, cylindrical windings could also be used with the sensor element moving along the cylindrical axis of the cylindrical winding.

If the inductive sensor is used to measure only an environmental factor such as temperature or humidity, the transmit aerial could have only one excitation winding as there is no requirement for the phase of the magnetic field to vary with position.

In the previous embodiments, the modulating signals are described as digital representations of sinusoidal signals. This is not strictly necessary and it is often convenient to use modulating signals that can be more easily generated using simple electronics. For example, the modulating signals could be digital representations of triangular waveforms.

In the previous embodiments, a quadrature pair of modulation signals are applied to carrier signals to generate first and second excitation signals which are applied to the sine coil 7 and cosine coil 9 respectively. However, the use of a quadrature pair of modulation signals is not essential because it is merely required that the information carrying components of the excitation signals are distinct in some way so that the relative contributions from the first and second excitation signals can be derived by processing the combined signal. For example, the modulation signals could have the same frequency and a phase which differs by an amount other than 90 degrees. Alternatively, the modulation signals could have slightly different frequencies thus giving rise to a continuously varying phase difference between the two signals.

In the described embodiments, the excitation signal generating circuitry and the sense signal processing circuitry is based on that used in the position sensor described in GB 2374424A which uses a variation of an LVPT sensor in which the excitation signal comprises a high frequency carrier signal modulated by a low frequency, and the sense signal processor demodulates the sense signal to leave a signal at the modulation frequency having a phase which varies with the position of a sensor element. Alternatively, a more conventional LVPT arrangement could be used. In an embodiment, a quadrature pair of signals at a single excitation frequency are respectively applied to the sine and cosine windings of a transmit aerial as described in the first embodiment. An intermediate coupling element as described in the first embodiment generates a signal component at twice the excitation frequency, and the signal processing circuitry passes the signal induced in the sense winding through at band pass filter which allows the signal component at twice the excitation frequency to pass. The phase of the signal component at twice the excitation frequency passed by the band pass filter is then measured to obtain a position measurement. As described previously, in order to avoid ambiguity in the position measurement caused by the phase doubling either the range of movement of the sensor element can be reduced or any additional coarse position measurement can be taken.

In the described embodiments, a transmit aerial is formed by two excitation windings and a receive aerial is formed by a single sensor winding. It will be appreciated that many other arrangements of transmit aerial and receive aerial in which the electromagnetic coupling between the transmit aerial and the receive aerial via an intermediate coupling element varies along a measurement path could be used. For example, the transmit aerial could be formed by a single excitation winding having an electromagnetic coupling to an intermediate coupling element which is substantially invariant with position, and the receive aerial could be formed by a pair of sensor windings having an electromagnetic coupling to the intermediate coupling element which varies with position according to respective different functions (e.g. the sine function and the cosine function respectively). The intermediate coupling element includes some form of frequency shifter so that when a signal at an excitation frequency is applied to the excitation winding, a signal is generated in the intermediate coupling element at a measurement frequency away from the excitation frequency. The respective strengths of signal components at the measurement frequency induced in the two sensor windings are measured to determine the location of the sensor element.

In the third to eighth embodiments, the layout of the sine winding, cosine winding and sense winding on the PCB 5 and the input winding and the output winding on the sensor element are such that:
1. The sine winding and the cosine winding are balanced with respect to the output winding so that current flowing through the transmit aerial directly induces negligible current signal into the output winding.
2. The sense winding is balanced with respect to the input winding so that current flowing through the input winding directly induces negligible current signal into the sense winding.

Although one specific layout of the windings is described, it will be appreciated that many different winding layouts are possible which achieve the same effects. It will also be appreciated that such arrangements could be used with sensors in which the intermediate coupling element does not have a frequency shifting property, for example the sensor described in GB 2374424A.

In the illustrated embodiments diodes have been incorporated into the intermediate coupling element.

As shown in FIG. 16, in an alternative embodiment an intermediate coupling element includes a light emitting diode 171 connected in series with a winding 173. In this alternative embodiment, a by-pass diode 175 is connected in parallel with the light emitting diode 171 to prevent excessive reverse biasing of the light emitting diode 171. In this way, when the intermediate coupling element is close to the transmit aerial the light emitting diode generates light so that a proximity indicator is formed. It will be appreciated that such a proximity indicator can be incorporated in conjunction with, for example, the position detectors of the illustrated embodiments.

While diodes have been used to introduce harmonic components into the current signal flowing through the intermediate coupling element, it will be appreciated that other forms of harmonic generator could be used. If diodes are used, it is preferable to use diodes with a low voltage drop, e.g. Schottky diodes, to increase signal levels.

In the first to eighth embodiments a modulation frequency of 3.9 kHz is used because it is well suited to digital processing techniques. This generally applies to frequencies in the range of 100 Hz to 100 kHz. Preferably, frequencies in the range 1-10 kHz are used, for example 2.5 kHz or 5 kHz.

In the first to eighth embodiments a carrier frequency of 2 MHz is used. Other carrier frequencies can be used, however using a carrier frequency above 1 MHz is preferred because it facilitates making the sensor element small.

1. A sensor for sensing a parameter to be measured, the sensor comprising:
a transmit aerial;
an intermediate coupling element;
a receive aerial electromagnetically coupled to the transmit aerial via the intermediate coupling element;
a signal generator operable to generate a periodic excitation signal at a first frequency, and arranged to apply the generated excitation signal to the transmit aerial in order to generate a sense signal in the receive aerial indicative of the value of the parameter to be measured; and
a signal processor operable to process the signal induced in the receive aerial to determine a value representative of the parameter being to be measured,
wherein the intermediate coupling element comprises a frequency shifter operable, in response to the periodic excitation signal being applied to the transmit aerial, to generate a sense signal in the receive aerial having a signal component at a second frequency which is different from the first frequency, and
wherein the signal processor is operable to process the signal at the second frequency to determine the value representative of the parameter to be measured.

2. A sensor according to claim 1, wherein said frequency shifter comprises a component having a non-linear voltage to current relationship.

3. A sensor according to claim 2, wherein said frequency shifter comprises a rectifier.

4. A sensor according to claim 3 wherein said rectifier is operable to perform half-wave rectification.

5. A sensor according to claim 4, wherein said rectifier is a diode.

6. A sensor according to claim 3, wherein said rectifier is operable to perform full-wave rectification.

7. A sensor according to claim 6, wherein said rectifier comprises a diode bridge arrangement.

8. A sensor according to claim 1, wherein the frequency shifter comprises an oscillator operable to oscillate at a frequency which is different from the first frequency.

9. A sensor according to claim 8, wherein the oscillation frequency of the oscillator is substantially away from any harmonic of the first frequency.

10. A sensor according to claim 1, wherein the intermediate coupling element comprises a winding which is coupled to the transmit aerial.

11. A sensor according to claim 10, wherein the intermediate coupling element further comprises a capacitor arranged so that at said first frequency the reactance of the capacitor substantially cancels out the reactance of the winding.

12. A sensor according to claim 10, wherein said winding is arranged to enable the winding to be substantially balanced with respect to the receive aerial, and said intermediate coupling element further comprises a second winding which is coupled to the receive aerial.

13. A sensor according to claim 12, wherein said second winding is arranged to enable the second winding to be substantially balanced with respect to the transmit aerial.

14. A sensor according to claim 12, wherein said second winding is substantially balanced with respect to the first winding of the intermediate coupling element.

15. A sensor according to claim 12, wherein the intermediate coupling element further comprises a capacitor arranged so that at said second frequency the reactance of the capacitor substantially cancels out the reactance of the second winding.

16. A sensor according to claim 1, wherein the transmit aerial and the receive aerial are fixed relative to a first member and the intermediate coupling element is fixed relative to a second member,
wherein at least one of the first and second members is movable relative to the other of the first and second members along a measurement path,
wherein the electromagnetic coupling between the transmit aerial and the receive aerial via the intermediate coupling element varies in dependence on the relative position of the first and second members,
and wherein the signal processor is operable to determine a value representative of the relative position of the first and second members.

17. A sensor according to claim 16, wherein the transmit aerial comprises first and second excitation windings and the receive aerial comprises a sensor winding,
wherein the first and second excitation windings are electromagnetically coupled to the sensor winding via the intermediate coupling element such that the electromagnetic coupling between the first and second excitation windings and the sensor winding varies in accordance with respective different functions along said measurement path.

18. A sensing apparatus according to claim 17, wherein the first and second excitation windings are arranged so that said first and second functions vary sinusoidally with position with the same period but are out of phase with each other.

19. A sensing apparatus according to claim 18, wherein the first and second functions are one quarter of a period out of phase with each other.

20. A sensing apparatus according to claim 1, wherein the signal generator is operable to apply a periodic modulation to the periodic signal at the first frequency at a modulation frequency which is less than the first frequency,
and wherein the signal processor comprises a demodulator operable to demodulate the induced signal in the receive aerial at the second frequency to obtain a demodulated signal at the modulation frequency.

21. A sensing apparatus according to claim 1, wherein the transmit aerial is formed by one or more conductive tracks on a planar substrate.

22. A sensing apparatus according to claim 21, wherein the planar substrate on which the transmit aerial is formed is a printed circuit board.

23. A sensing apparatus according to claim 1, wherein the intermediate coupling element comprises one or more conductive tracks formed on a planar substrate.

24. A sensing apparatus according to claim 23, wherein the planar substrate of the intermediate coupling element is a printed circuit board.

25. A proximity indicating apparatus comprising:
a first member comprising a transmit aerial;
a second member comprising a coupling element operable to couple electromagnetically with the transmit aerial; and
a signal generator operable to generate an excitation signal, and arranged to apply the generated excitation signal to the transmit aerial in order to generate a signal in the coupling element,
wherein the coupling element comprises a light emitting diode which, in response to the periodic excitation signal being applied to the transmit aerial, is operable to emit light if the signal induced in the coupling element is sufficient to make the light emitting diode conducting.

26. A proximity indicating apparatus according to claim 25, further comprising a by-pass diode connected in parallel with the light emitting diode.

27. A sensor for sensing a parameter to be measured, the sensor comprising:
a transmit aerial;
an intermediate coupling element;
a receive aerial electromagnetically coupled to the transmit aerial via the intermediate coupling element;
a signal generator operable to generate a periodic excitation signal at a first frequency, and arranged to apply the generated excitation signal to the transmit aerial in order to generate a sense signal in the receive aerial indicative of the value of the parameter to be measured; and
a signal processor operable to process the signal induced in the receive aerial to determine a value representative of the parameter to be measured,
wherein the intermediate coupling element comprises a first winding which is coupled to the transmit aerial and is arranged to enable the first winding to be substantially balanced with respect to the receive aerial, and said intermediate coupling element further comprises a second winding which is coupled to the receive aerial and is arranged to enable the second winding to be substantially balanced with respect to the transmit aerial.
